(19) United States
(12) Patent Application Publication
(10) Pub. No.: US 2011/0293331 A1
(43) Pub. Date: Dec. 1, 2011

(54) SURFACE-EMITTING LASER AND IMAGE FORMING APPARATUS USING THE SAME

(75) Inventors: Yasuhisa Inao, Tokyo (JP); Mitsuhiro Ikuta, Kawasaki-shi (JP); Tetsuya Takeuchi, Yokohama-shi (JP)

(73) Assignee: CANON KABUSHIKI KAISHA, Tokyo (JP)

(21) Appl. No.: 13/111,282

(22) Filed: May 19, 2011

(30) Foreign Application Priority Data
May 27, 2010 (JP) 2010-121228

(51) Int. Cl. G03G 15/04; H01S 5/323; H01S 5/187

(52) U.S. Cl. 399/220; 372/46.013

(57) ABSTRACT

This invention provides a surface-emitting laser that can prevent delamination at the interface of a selective oxidation layer and a spacer layer, while suppressing any rise of voltage, to improve the reliability of operation.

### BACKGROUND OF THE INVENTION

1. Field of the Invention

The present invention relates to a surface-emitting laser. More particularly, it relates to a surface-emitting laser having a current confinement structure obtained by oxidation and also to an image forming apparatus using the same.

2. Description of the Related Art

A vertical cavity surface-emitting laser (to be referred to as VCSEL hereinafter) emits a laser beam perpendicularly relative to the in-plane direction of a semiconductor substrate.

A VCSEL is generally so configured as to have an active region sandwiched between a pair of distributed Bragg reflectors (to be referred to as DBRs hereinafter) laminated on a substrate.

Particularly, a surface-emitting laser that emits red light (620 to 700 nm) is prepared generally by using an AlGaInP-based material for the active region.

For example, U.S. Pat. No. 5,351,256 describes a VCSEL having an active layer formed by using GalnP/AlGaInP quantum well in the active region and sandwiching it between AlInP spacer layers.

The above U.S. patent describes that any overflow of electrons can be effectively suppressed by using AlInP for the spacer layers thereof. An AlAs/AlGaAs multilayer film structure is employed for DBRs.

“Red vertical cavity surface-emitting lasers (VCSELs) for consumer applications” (Firecomms Ltd, Proc. of SPIE Vol. 6908 69080G-1) describes another typical VCSEL that emits red light.

In the above-cited instance, an AlGaAs/AlGaAs multilayer film structure of high Al composition of 95% and Al composition of 50% is employed for DBRs.

The VSCEL of this instance is differentiated from that of U.S. Pat. No. 5,351,256 by replacing one of the DBR layers that contain Al to a high ratio in the chemical composition by an AlGaAs layer with high Al composition (generally containing Al by not less than 98%) that can be oxidized in a high temperature and steam atmosphere. This layer will be referred to as selective oxidation layer hereinafter.

A red VCSEL having a high quality current confinement structure can be prepared by exposing the selective oxidation layer to a high temperature and steam atmosphere to turn it into AlOx for electric insulation and to limit the current injection to a narrow region.

Then, as is popularly well known, an electric current can get to the active layer before it spreads by arranging the current confinement structure close to the active layer to maximally exploit the advantages of the current confinement structure.

A popular exemplar conventional art arrangement will now be described below as an example of combining the above-described conventional art arrangements.

An n-type DBR, an n-type spacer layer, a p-type spacer layer and a p-type DBR can be formed in a manner as described below. An AlGaInP-based active layer is arranged at a position sandwiched between an n-type spacer layer and a p-type spacer layer.

An n-type spacer layer is formed by using an n-type AlGaInP-based material containing impurity atoms that operate as donors of Si, Se and so on.

An n-type DBR is formed by using an n-type AlGaAs-based material.

A p-type spacer layer is formed by using p-type AlInP containing impurity atoms that operate as acceptors of Zn, Mg and so on.

A p-type DBR is formed by using a p-type AlGaAs-based material containing impurity atoms that operate as acceptors of C, Zn, Mg and so on.

AlInP that can effectively suppress an overflow of electrons is employed for a p-type spacer layer.

A selective oxidation layer formed by using AlGaAs with an Al composition of 0.98 is arranged to adjoin the p-type spacer layer.

With the above-described arrangement, an electric current can be maximally brought close to the active layer in order to make it get to the active layer without spreading.

A material that shows an oxidation rate remarkably different from the oxidation rate of the selective oxidation layer needs to be used for the AlGaAs-based DBR of the p-type DBR for the purpose of achieving selective oxidation of the selective oxidation layer.

More specifically, Al_{0.9}Ga_{0.1}As can be used for a low refractive index layer, and Al_{0.5}Ga_{0.5}As can be used for a high refractive index layer.

A high Al composition material shows a high oxidation rate. As shown in FIG. 3, Al_{0.9}Ga_{0.1}As shows an oxidation rate that is slower than the oxidation rate of Al_{0.98}Ga_{0.02}As that is to be used as selective oxidation layer about a digit to make it possible to selectively oxidize only the selective oxidation layer.

FIG. 2 shows the active layer and the p-type semiconductor part of a conventional art red surface-emitting laser that are characteristic sites of giving rise to a problem in such an arrangement.

As a result of intensive research efforts, the inventors of the present invention found that a major problem that relates to the reliability of a surface-emitting laser arises when a p-type AlInP spacer layer 202 and a selective oxidation layer 203 adjoin each other as shown in FIG. 2. This will be described below.

As is well known, when AlGaAs is made to glow to form a selective oxidation layer 203 on a p-type spacer AlInP layer 202, defects can easily occur to degrade the crystallinity at the interface where the V-group material is switched from phosphorus (P) to arsenic (As) by 100%.

The cause of this phenomenon is believed to be the large differences of chemical properties between As and P (saturated vapor pressure, binding energy, lattice constant, etc.). They degrade the interface quality and ultimately lead to a short life span of the device.

When a selective oxidation layer 203 is subjected to oxidation in a high temperature and steam atmosphere to form a current confinement structure, the selective oxidation layer 203 is degraded and turned into oxides of AlGaAs (mainly Al oxides: AlOx) as a matter of course.

As is known, stress is produced in the selective oxidation layer 203 and its surroundings as the selective oxidation layer 203 is oxidized because the material thereof is degraded and the film volume is reduced.

The AlInP of the p-type spacer layer adjoins the selective oxidation layer 203 in the above-described arrangement of the conventional art red surface-emitting laser.

Thus, the selective oxidation layer adjoins the interface of phosphorus (P) and arsenic (As) where defects can easily occur from the initial stages of crystal growth so that the stress due to oxidation can strongly affect the selective oxidation layer. The inventors of the present invention found that delamination easily takes place at the P/As interface where defects are liable to exist for this reason.

Such delamination is a problem specific to red surface-emitting lasers formed by using an AlGaInP-based material for the active region and an AlGaAs-based material for the DBR and having a current confinement structure produced by selective oxidation.

As a result of that the material of the selective oxidation layer is degraded due to the oxidation process and the film volume changes, large stress occurs at the interface between the p-type spacer layer AlInP and the selective oxidation layer AlGaAs so that delamination can take place at the interface. Particularly, delimination takes place remarkably between AlInP and the oxidized selective oxidation layer in a rapid thermal annealing (RTA) process that is generally conducted to reduce the contact resistance of the semiconductor/metal interface of the device electrode after preparing a surface-emitting laser. Such delamination can completely destruct the surface-emitting laser.

Additionally, heat can be locally generated in the current confinement structure to give rise to delamination at the interface thereof when the device is actually operated and electrically energized continuously.

Thus, devices of the above-described type entail a poor yield in terms of good products and delamination can take place in operation to consequently destruct the device. Particularly, destruction takes place in the inside and hence cannot be detected by an appearance inspection to make difficult to sort out good devices so that consequently the reliability of devices and hence entire systems such as image forming apparatus incorporating such devices will be degraded.

### SUMMARY OF THE INVENTION

In view of the above-identified problems, an object of the present invention is to provide a surface-emitting laser that can prevent delamination at the interface of the selective oxidation layer and the spacer layer, while suppressing the voltage rise, and improve the reliability and also an image forming apparatus using the same.

A surface-emitting laser according to the present invention comprise: an n-type semiconductor Bragg reflector arranged on a substrate: an active layer including AlGaInP formed on the n-type semiconductor Bragg reflector; a p-type spacer layer including AlInP formed on the active layer; a selective oxidation layer including Al_{z}Ga_{1-z}As formed on the p-type spacer layer; an p-type semiconductor Bragg reflector including AlGaAs formed on the selective oxidation layer; a first intermediate layer including AlₓGa₁₋ₓAs arranged between the selective oxidation layer and the p-type spacer layer so as to adjoin the selective oxidation layer; a second intermediate layer including Al_{y}Ga_{1-y}As arranged between the selective oxidation layer and the p-type spacer layer so as to adjoin the first intermediate layer; and a third intermediate layer including AlGaInP arranged between the selective oxidation layer and the p-type spacer layer so as to adjoin the second intermediate layer, wherein the z, y, x of the above material satisfy the relationship of z>y>x.

Thus, the present invention can realize a surface-emitting laser that can prevent delamination at the interface of the selective oxidation layer and the spacer layer, while suppressing the voltage rise, and improve the reliability and also an image forming apparatus using the same.

Further features of the present invention will become apparent from the following description of exemplary embodiments with reference to the attached drawings.

### BRIEF DESCRIPTION OF THE DRAWINGS

FIG. 1 is a schematic illustration of a semiconductor laminated structure for forming an embodiment of red surface-emitting laser according to the present invention.

FIG. 2 is a schematic illustration of a semiconductor laminated structure for forming a red surface-emitting laser of the conventional art.

FIG. 3 is a graph illustrating the relationship between the oxidation rate and the Al composition ratio.

FIG. 4 is a schematic cross sectional view of the semiconductor laminated structure of an embodiment of red surface-emitting laser according to the present invention.

FIG. 5 is a schematic illustration of the relationship between the configuration of the resonator and the standing wave of light of Example 1 of the present invention.

FIG. 6 is a schematic cross sectional view of a red surface-emitting laser of Example 1 of the present invention.

FIG. 7 is a schematic cross sectional view of a red surface-emitting laser of Example 2 of the present invention.

FIG. 8 is a schematic illustration of the relationship between the configuration of the resonator and the standing wave of light of Example 2 of the present invention.

FIG. 9A is a schematic illustration of an image forming apparatus using a surface-emitting laser array of Example 3 of the present invention.

FIG. 9B is a schematic illustration of an image forming apparatus using a surface-emitting laser array of Example 3 of the present invention.

FIG. 10 is a schematic illustration of the band lineup at the top of valence band of the structure of FIG. 1.

### DESCRIPTION OF THE EMBODIMENTS

Preferred embodiments of the present invention will now be described in detail in accordance with the accompanying drawings.

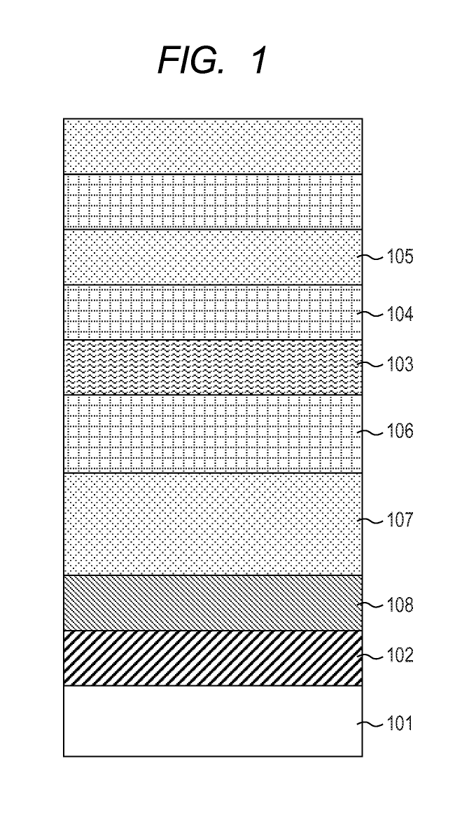

An exemplar configuration of a red surface-emitting laser formed by laminating an n-type semiconductor Bragg reflector (n-type DBR), a p-type semiconductor Bragg reflector (p-type DBR) and an active layer arranged between the two Bragg reflectors, on a substrate will be described below by referring to FIG. 1.

FIG. 1 shows an active layer 101, a p-type spacer layer 102, a p-type selective oxidation layer 103, p-type DBRs (p-type DBR—high refractive index layer) 104 and (p-type DBR—low refractive index layer) 105, a first p-type intermediate layer 106, a second p-type intermediate layer 107 and a third p-type intermediate layer 108 that form a semiconductor laminated structure for the red surface-emitting laser of this embodiment, of which the first, second and third p-type intermediate layers characterize this embodiment.

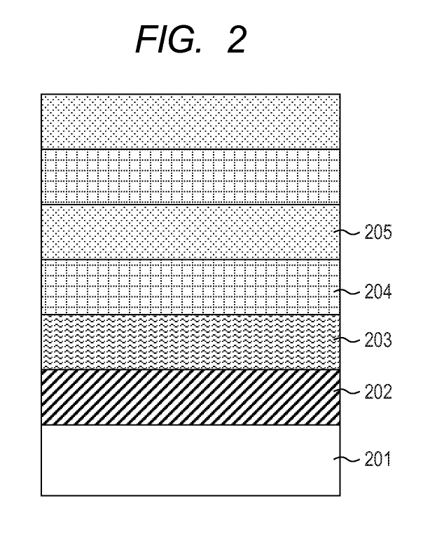

FIG. 2 shows an active layer 201, a p-type spacer layer 202, a selective oxidation layer 203 and p-type DBRs 204 and 205 that form a semiconductor laminated structure for a popular red surface-emitting laser of the conventional art.

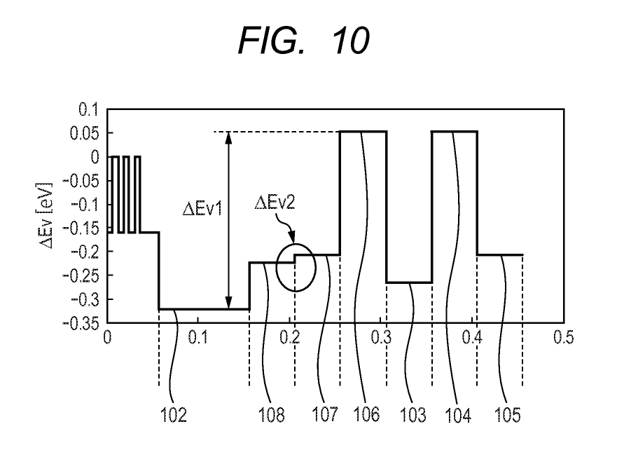

FIG. 10 shows the band lineup at the top of the valence band of FIG. 1.

In the band diagram of FIG. 10, the band line up is shown with the differences from GalnP that is employed as quantum well and assumed to be “0”, or ΔEv.

When a semiconductor that is originally of p-type is doped, Fermi level is found near the valence band and the tops of the valence bands substantially agree among materials.

However, if a band lineup is formed with substantially unified Fermi levels, ΔEv remains among the materials in the form of spike and notch. ΔEv is very significant for the present invention and hence, for the purpose of simplification, FIG. 10 shows a flat band lineup in an undoped situation where ΔEv can be determined with ease. The characteristic configuration of the semiconductor laminated structure of this embodiment is that three layers including a first p-type intermediate layer 106 formed by AlGaAs where oxidation does not progress in any oxidation process, a second p-type intermediate layer 107 of AlGaAs for adjusting band gaps, and a third p-type intermediate layer 108 of AlGaInP are arranged between the selective oxidation layer and the p-type AlInP spacer layer that is formed on the active layer.

In other words, the above-described first through third p-type intermediate layers are added to the semiconductor laminated structure of the above-described popular red surface-emitting laser of the conventional art.

More specifically, the p-type semiconductor Bragg reflector is made of an AlGaAs-based material, the active layer is made of an AlGaInP-based material, the p-type spacer layer is made of AlInP, and the selective oxidation layer is made of Al_{z}Ga_{1-z}As.

Additionally, the first intermediate layer is made of AlₓGa₁₋ₓAs and the second and third intermediate layers are respectively made of Al_{y}Ga_{1-y}As and AlGaInP.

The composition ratios of z, y, x of the above materials satisfy a relationship of z>y>x and the positions at the top of the valence band sequentially falls in the order of the second intermediate layer, the third intermediate layer and the p-type spacer layer. These layers will be described in detail hereinafter.

Now, an exemplar arrangement of the layers that characterizes this embodiment will be described below. The first p-type intermediate layer 106 is a layer that prevents the layers adjoining the selective oxidation layer 103 from being oxidized in an operation of oxidizing the selective oxidation layer 103 for forming a current confinement structure.

The first p-type intermediate layer 106 is required to be formed by using a material that is oxidized at a very low rate if compared with the selective oxidation layer 103.

The oxidization rate of AlGaAs is described in detail in Non-Patent Literature “Advances in Selective Wet Oxidation of AlGaAs Alloys, IEEE JOURNAL OF SELECTED TOPICS IN QUANTUM ELECTRONICS, VOL. 3. NO. 3, JUNE 1997”.

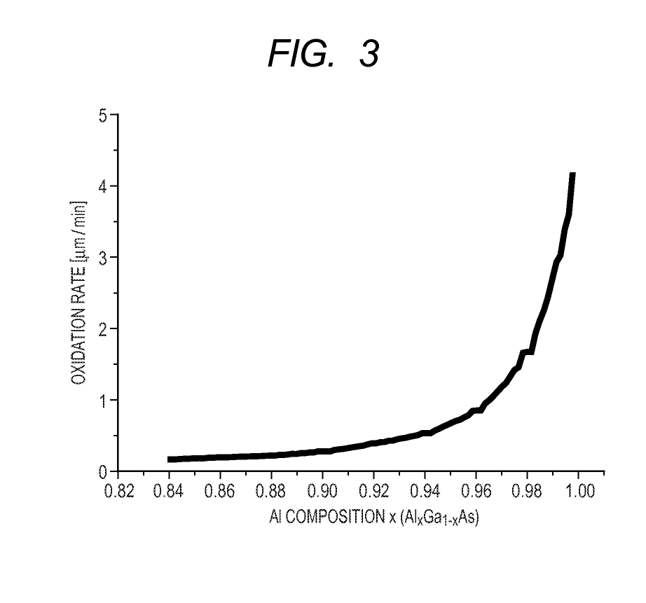

FIG. 3 shows values of the oxidation rate.

More specifically, an AlₓGa₁₋ₓAs (x<0.8) material in a range of Al composition where the oxidation rate is smaller than that of the oxidation layer by a digit and does not significantly change regardless of the Al composition is employed.

Preferably, AlGaAs of an Al composition that does not absorb the red band including the oscillation wavelength and shows a low Al composition value of 0.5≦x≦0.6 is employed. More preferably, Al_{0.5}Ga_{0.5}As which shows the lowest oxidation rate within the above range is employed. The reason for this is that, if Al_{0.9}Ga_{0.1}As which is a material that is hardly oxidized when left alone (although the oxidation rate is high if compared with an Al composition<0.8) is employed and arranged at a position adjoining a selective oxidation layer whose Al composition is not less than 0.98, it will be oxidized at the time of selective oxidation.

The second p-type intermediate layer 107 and the third p-type intermediate layer 108 are for filling the energy difference (ΔEv: see FIG. 10) ΔEv1 between the first p-type intermediate layer 106 and the p-type AlInP spacer layer 102 at the top of the valence band shown in the band lineup of FIG. 10. Particularly, the use of AlGaAs showing a low Al composition is required for the p-type intermediate layer 1. Then, the top of the valance band inevitably becomes high so that ΔEv relative to the p-type AlInP spacer layer desirably shows a large value.

When ΔEv is large, it gives rise to a large barrier for holes that are carriers for the p-type to entail a rise of drive voltage, which by turn increases the generated heat and reduces the output of light.

For this reason, as the second p-type intermediate layer 107, AlAs that is lowest at the top of the valence band among AlGaAs-based materials may desirably be employed in order to fill the ΔEv. However, AlGaAs needs to be employed from the viewpoint of selective oxidation because its Al composition is lower than the selective oxidation layer 103 and it is hardly oxidized.

More specifically, AlₓGa₁₋ₓAs (0.85<x<0.95), preferably Al_{0.9}Ga_{0.1}As, is employed.

However, if Al_{0.95}Ga_{0.05}As that is lowest at the top of the valence band among materials within the above-described range is employed for the second p-type intermediate layer 107, ΔEv relative to the p-type AlInP spacer layer 102 remains to be about 70 meV.

Particularly, crystallinity is degraded at the P/As interface of different V-group materials and the influence of degraded crystallinity tends to become significant if the value of ΔEv is made equal to that of ΔEv at a hetero interface of materials of the same kind.

For this reason, a layer made of an AlGaInP-based material is introduced as the third p-type intermediate layer 108 for filling ΔEv between the second p-type intermediate layer 107 and the p-type AlInP spacer layer 102.

At this time, a material that is not necessarily be found intermediate between the second p-type intermediate layer and the p-type AlInP spacer layer at the top of the valence band but minimizes ΔEv2, or the energy difference (ΔEv shown in FIG. 10) at the P/As interface is desirably selected.

More specifically, if, for example, Al_{0.95}Ga_{0.05}As is employed for the second p-type intermediate layer 107, (Al_{0.8}Ga_{0.2})InP is employed for the third intermediate layer 108. Then, ΔEv will be about 14 meV to make the top of the valence band at the side of Al_{0.8}Ga_{0.2}InP low.

As a result of intensive research efforts and a series of experiments, the inventors of the present invention have found that the drive voltage is not raised significantly if ΔEv between the second p-type intermediate layer and the third p-type intermediate layer is not more than about 20 meV.

The rise of drive voltage, if any, can be suppressed further by using a composition gradient layer whose Al composition shows a gradient at the hetero interface of materials where the same V-group element is employed.

More specifically, a composition gradient layer whose Al composition shows a gradient is arranged between the first p-type intermediate layer 106 and the second p-type intermediate layer 107.

To be more specific, when the first p-type intermediate layer 106 and the second p-type intermediate layer 107 are formed by using Al_{0.5}Ga_{0.5}As and Al_{0.9}Ga_{0.1}As respectively, a composition gradient layer whose Al composition mildly changes from 0.5 to 0.9 from the side of the first p-type intermediate layer is arranged between them.

As another specific exemplar arrangement, a composition gradient layer whose Al composition mildly changes may be arranged between the third p-type intermediate layer 108 and the p-type AlInP spacer layer 102.

To be more specific, when the third p-type intermediate layer is formed by using Al_{0.35}Ga_{0.15}In_{0.5}P, a composition gradient layer whose Al composition mildly changes from 0.35 to 0.5 from the side of the third p-type intermediate layer may be arranged.

By using an arrangement as described above, all the hetero barriers at the above-described interface can be made very small so that the rise of drive voltage can be suppressed without giving rise to a problem of delamination.

Additionally, each of the first p-type intermediate layer 106 and the second p-type intermediate layer 107 may have a thickness of λ/4n (n: refractive index of medium) relative to the oscillation wavelength λ.

With such an arrangement, the first p-type intermediate layer and the second p-type intermediate layer can function as part of the p-type DBR and hence prevent the reflectance of the p-type DBR from falling.

The first p-type intermediate layer 106, the second p-type intermediate 107 and the third p-type intermediate layer 108 that structurally characterize this embodiment are described above.

However, note that the Al composition values of the above-described materials are only examples and the advantages of the present invention are secured so long as the above-described ranges of values are observed.

The values of ΔEv in the above description are computed on the basis of the values described in “Interface properties for GaAs/InGaAlP heterojunctions by the capacitance-voltage profiling technique, Appl. Phys. Lett. 50, 906 (1987)”.

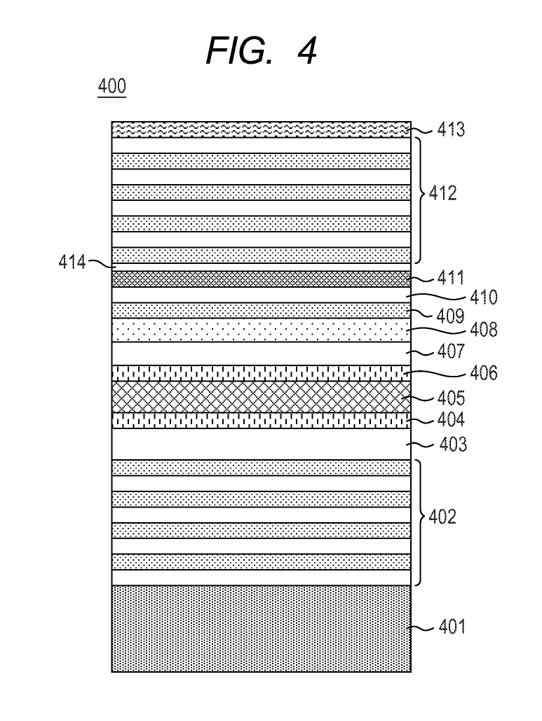

Now, the structure that characterizes the red surface-emitting laser of this embodiment will be described below by referring to FIG. 4.

In the red surface-emitting laser 400 of this embodiment, the following layers are sequentially laminated on a structure formed by sequentially laminating an n-type GaAs substrate 401, an n-type DBR 402, an n-type spacer layer 403 and an active layer 405.

That is, the p-type DBR 412 and p-type contact layer 413 are sequentially laminated on a structure formed by sequentially laminating the p-type AlInP spacer layer 407, third p-type intermediate layer 408, second p-type intermediate layer 409, first p-type intermediate layer 410, p-type selective oxidation layer 411.

The n-type DBR 402 is formed by laminating a set of two AlGaAs layers that are different from each other with Al compositions (refractive indexes), and are a unit of repetition, repeatedly for a plurality of times.

Particularly, in the case of a red surface-emitting laser that is strongly affected by heat, its heat emitting performance is improved to realize a high output level when AlAs showing an excellent thermal conductivity is employed for a layer having a high Al composition (low refractive index material).

The p-type DBR 412 is also formed by laminating a set of two AlGaAs layers that are different from each other with Al compositions (refractive indexes), and are a unit of repetition, repeatedly for a plurality of times.

AlₓGa₁₋ₓAs (0.7≦x≦0.95, preferably 0.8≦x≦0.9) is appropriately selected for the layer having a higher Al composition of the two layers. The above range is selected from the viewpoint that its oxidation rate is desirably lower than that of the selective oxidation layer for preparing the device. AlₓGa₁₋ₓAs (0.4<x<0.7, preferably 0.45<x<0.6) is appropriately selected for the layer having a lower Al composition for both the n-type and the p-type.

The value of x may appropriately be selected so as to be not less than 0.4 and able to secure a sufficient difference of refractive index between it and the other DBR layer so that light of the related wavelength may not be absorbed though depending on wavelength from the active layer. For example, X=0.5 may be a preferable choice for AlₓGa₁₋ₓAs.

AlInP is employed for the p-type spacer layer 407 because it provides the highest effect for suppressing any overflow of electrons.

GaAs is formed on the p-type DBR as a p-type contact layer 413. The GaAs is doped as p-type and the doping concentration is not less than 5×10¹⁸ cm⁻³, preferably not less than 5×10¹⁹ cm⁻³, most preferably not less than 1×10²⁰ cm⁻³. The contact resistance can become too small when the electrodes are formed by using a metal material in a latter step if the doping concentration is higher.

### EXAMPLES

Now, the present invention will be described by way of examples.

### Example 1

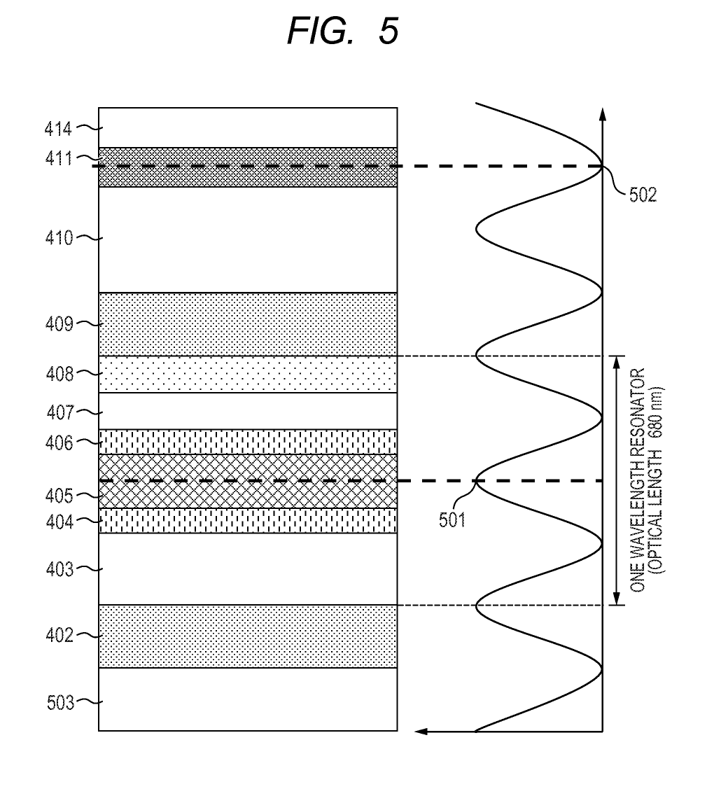

An exemplar configuration of the semiconductor laminated structure of the red surface-emitting laser of this example will be described below by referring to FIGS. 4 and 5.

The VCSEL structure of this example is formed by using the layers listed below.

It comprises an n-type GaAs substrate 401, an n-type DBR 402 formed by repetitively arranging n-type Al_{0.9}Ga_{0.1}As/Al_{0.5}Ga_{0.5}As, a spacer layer 403 formed by n-type Al_{0.35}Ga_{0.15}In_{0.5}P, a barrier layer 404 formed by undoped Al_{0.25}Ga_{0.25}In_{0.5}P, a quantum well active layer 405 formed by Ga_{0.56}In_{0.44}P/Al_{0.25}Ga_{0.25}In_{0.5}P, a barrier layer 406 formed by undoped Al_{0.25}Ga_{0.25}In_{0.5}P, a spacer layer 407 formed by p-type Al_{0.5}In_{0.5}P, a third p-type intermediate layer 408 formed by p-type Al_{0.35}Ga_{0.15}In_{0.5}P, a second p-type intermediate layer 409 formed by p-type Al_{0.9}Ga_{0.1}As, a first p-type intermediate layer 410 formed by p-type Al_{0.5}Ga_{0.5}As, a selective oxidation layer 411 formed by p-type Al_{0.98}Ga_{0.02}As, a p-type Al_{0.5}Ga_{0.5}As layer 414, a p-type DBR 412 formed by repetitively arranging p-type Al_{0.9}Ga_{0.1}As/Al_{0.5}Ga_{0.5}As and a contact layer 413 formed by p-type GaAs.

A red surface-emitting laser that oscillates with a wavelength of 680 nm is formed in this instance. Firstly, the DBR 402 formed by arranging n-type Al_{0.9}Ga_{0.1}As/Al_{0.5}Ga_{0.5}As and the DBR 412 formed by arranging p-type Al_{0.9}Ga_{0.1}As/Al_{0.5}Ga_{0.5}As will be described. In each of the DBRs, an Al_{0.9}Ga_{0.1}As and an Al_{0.5}Ga_{0.5}As are formed so as to make them show an optical thickness of ¼ of the wavelength.

In actuality, a composition gradient layer of about 20 nm is arranged between each Al_{0.9}Ga_{0.1}As layer and a neighboring Al_{0.5}Ga_{0.5}As layer in order to reduce the electric resistance.

Note that the optical thickness of ¼ of the wavelength includes that of the composition gradient layer.

The p-type DBR 412 is doped with impurities that operate as acceptors such as C and Zn in order to allow an electric current to flow through it.

The n-type DBR 402 is doped with impurities that operate as donors such as Si and Se.

Each of the DBRs may be modulation-doped in such a way that it is doped with a reduced rate at the loop of the standing wave of the internal field intensity distribution and with a raised rate at the node of the standing wave in order to minimize the absorption of light in the inside of the DBR.

Since a device structure of taking out light from the substrate surface, or from the side of the p-type layers, is adopted in this example, the p-type DBR 412 is formed by repetitively arranging the component pairs for about 34 times in order to form a reflector showing an optimum light taking out efficiency.

On the other hand, because no light needs to be taken out from the side of the n-type layers, the reflectance is maximally raised to reduce the threshold current by repetitively arranging the component pairs for about 60 times.

The second p-type intermediate layer 409 formed by p-type Al_{0.9}Ga_{0.1}As is made to have an optical thickness of ¼ of the wavelength.

The first p-type intermediate layer 410 formed by p-type Al_{0.5}Ga_{0.5}As is made to be 84.8 nm thick and have an optical thickness of not less than ¼ of the wavelength.

The selective oxidation layer 411 formed by p-type Al_{0.98}Ga_{0.02}As is made to be 30 nm thick and arranged on the first p-type intermediate layer 410.

Subsequently, the p-type Al_{0.5}Ga_{0.5}As layer 414 is arranged with a thickness of 35.7 nm.

The first p-type intermediate layer 410, the p-type selective oxidation layer 411 and the p-type Al_{0.5}Ga_{0.5}As layer 414 have respective refractive indexes of 3.46, 3.10 and 3.46 and the total thickness of the three layers is made to be 510 nm that produces an optical thickness of 3λ/4.

The thickness of the first p-type intermediate layer is so selected as to make the center of the p-type selective oxidation layer 411 agree with the node of the standing wave.

The total optical thickness of the first p-type intermediate layer, the p-type selective oxidation layer and the p-type Al_{0.5}Ga_{0.5}As layer and the optical thickness of the second p-type intermediate layer are integer times of λ/4, and these layers operate as part of the p-type DBR.

A composition gradient layer may be arranged at each of the interfaces of the four layers as in the case of the DBR.

If such an arrangement is employed, a composition gradient layer of about 20 nm may be arranged at each of the interfaces, while maintaining the thickness of 30 nm for the p-type selective oxidation layer. Then, each of the above-described optical thicknesses includes the optical thickness of a composition gradient layer.

Now, formation of a resonator will be described below.

In this example, a one-wavelength cavity having a configuration that is normally employed for a VCSEL is adopted.

The optical thickness of a one-wavelength cavity with an oscillation wavelength of 680 nm is 680 nm.

The resonator refers to a region surrounded by the two DBRs and hence is formed by the n-type spacer layer, the active layer, the barrier layer, the p-type spacer layer and the third p-type intermediate layer.

The active layer needs to be arranged at the loop of the standing wave in order to maximize the interaction of light and carriers. In this instance, the active layer is arranged at the center position of the resonator.

An actual example of resonator will be described below, taking the above requirements into consideration.

The active layer 405 is formed by four 6 nm GalnP quantum wells and three barrier layers formed of 6 nm Al_{0.25}Ga_{0.25}In_{0.5}P, to make the actual thickness of the layer equal to 42 nm.

The refractive index of the GalnP layer and that of the Al_{0.25}Ga_{0.25}In_{0.5}P layer are respectively 3.56 and 3.37 for the emission wavelength of 680 nm so that the optical thickness of the active layer 405 is 146 nm.

An optical thickness of 340 nm, which is ½ of 680 nm, produced by adding 73 nm that is a half of the optical length of the active layer 405, the optical thickness of the barrier layer 404 formed by undoped Al_{0.25}Ga_{0.25}In_{0.5}P and that of the spacer layer 403 formed by n-type Al_{0.35}Ga_{0.15}In_{0.5}P will be satisfactory. The barrier layer 404 formed by undoped Al_{0.25}Ga_{0.25}In_{0.5}P and the spacer layer 403 formed by n-type Al_{0.35}Ga_{0.15}In_{0.5}P are made to have respective thicknesses of 20 nm and 60.5 nm. Since their refractive indexes are respectively 3.37 and 3.30, the optical thickness of the two layers is 267 nm.

Then, the optical thickness will be 340 nm when 73 nm that is a half of the optical length of the active layer 405 is added to the above value so that the center of the active layer 405 is made to agree with the loop 501 of the standing wave as shown in FIG. 5. At the p side, an optical thickness of the remaining 340 nm produced by adding 73 nm that is a half of the optical thickness of the active layer, the optical thickness of the barrier layer 406 formed by undoped Al_{0.25}Ga_{0.25}In_{0.5}P, that of the spacer layer 407 formed by p-type Al_{0.5}In_{0.5}P and that of the third intermediate layer 408 formed by p-type Al_{0.35}Ga_{0.15}In_{0.5}P will be satisfactory.

While Al_{0.35}Ga_{0.15}In_{0.5}P is employed at the n side, Al_{0.5}In_{0.5}P is employed at the p side in order to make the hetero barrier as large as possible and suppress any overflow of electrons as much as possible and doped to a concentration of about 1×10¹⁸ cm⁻³. Zn and Mg are employed as dopant.

The barrier layer 406, the p-type Al_{0.5}In_{0.5}P spacer layer 407 and the third intermediate layer 408 formed by p-type Al_{0.35}Ga_{0.15}In_{0.5}P are respectively made to have thicknesses of 20 nm, 31 nm and 30.2 nm.

Since their respective refractive indexes are 3.37, 3.22 and 3.30, the optical thickness of the three layers is 267 nm, and the total optical thickness of 340 nm is obtained when 73 nm, which is a half of the optical thickness of the active layer 405, is added thereto.

When Al_{0.9}Ga_{0.1}As is employed for the second p-type intermediate layer 409 in order to make ΔEv between the third p-type intermediate layer 408 and the second p-type intermediate layer 409 less than 20 meV, Al_{0.35}Ga_{0.15}In_{0.5}P is employed for the third p-type intermediate layer 408.

With this arrangement, ΔEv is about 18 meV so that any rise of the drive voltage can be suppressed. Thus, the optical thickness of the n layers including the undoped barrier layer, that of the active layer and that of the p layers including the undoped barrier layer are respectively 267 nm, 146 nm and 267 nm (a total of 680 nm), which agrees with the optical thickness of the one-wavelength cavity.

A multilayer film reflector is formed at each side of the resonator. Both the multilayer film reflector at the n side and the multilayer film reflector at the p side are arranged in such a way that the loop of the standing wave agrees with the interfaces of the resonator and the multilayer film reflectors.

More specifically, a low refractive index material, which is the n-type Al_{0.9}Ga_{0.1}As layer 503 in this instance, is made to adjoin the resonator and a high refractive index material, which is the Al_{0.5}Ga_{0.5}As layer 401 in this instance, is arranged at the other side of the latter.

As for the p-type side, the second p-type intermediate layer 409 and so on operate as part of the p-type DBR so that p-type Al_{0.9}Ga_{0.1}As layer that is a low refractive index material is arranged next to the p-type Al_{0.5}Ga_{0.5}As layer 414 and a high refractive index material, which is Al_{0.5}Ga_{0.5}As in this instance, is further arranged thereon. The component pairs are arranged repetitively for a necessary number of times both at the p-type side and at the n-type side (34 pairs for the p side and 60 pairs for the n side).

When actually preparing the device, a wafer having layers of the above-described thicknesses is formed by means of a crystal growth technique.

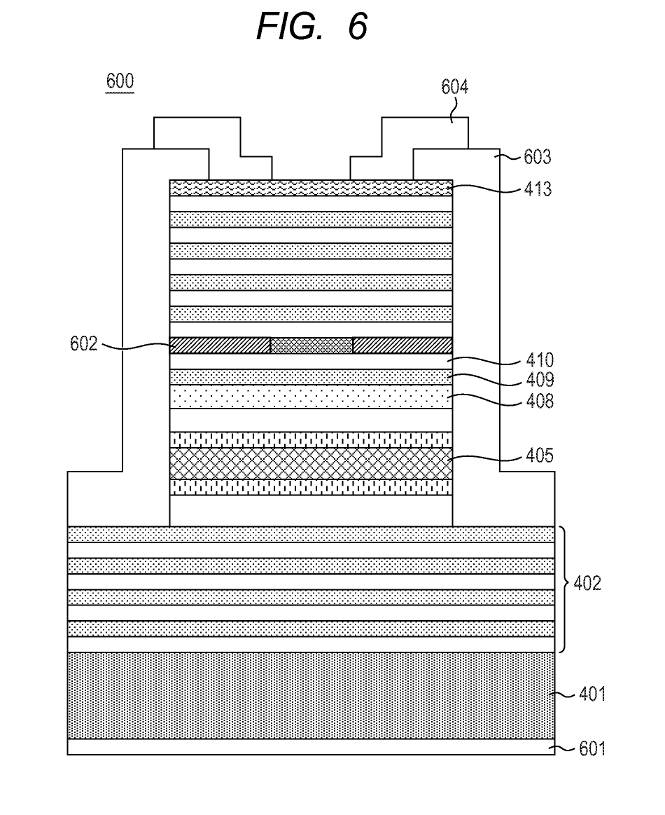

For example, a layered structure is formed by means of an organic metal compound growth system or a molecular beam epitaxy system. After forming a wafer structure, a laser device 600 having a configuration as shown in FIG. 6 is prepared by a normally employed semiconductor process technique.

Note that, in FIG. 6, the layers having respective features same as those described above by referring to FIG. 4 are denoted by the same reference numbers.

Post is formed by photolithography and semiconductor etching and a current confinement layer 602 is formed by selective oxidation.

Subsequently, an insulator film 603 is formed by deposition and made to open only at the region to be brought into contact with a p-GaAs contact layer 413 and a p side electrode 604 is formed. A complete device is finally produced by forming an n side electrode 601 at the rear side of the wafer.

No P/As interface exists between the p-type AlInP spacer layer and the AlGaAs for selective oxidation in the device prepared in this way according to the present invention.

Therefore, the rise of drive voltage, if any, can be suppressed because no interlayer delamination occurs at the above-described interfaces and no large hetero barrier (ΔEv) exists in the device.

For this reason, the device can be used for high light output power operations and prevent any increase of emitted heat from taking place to consequently extend the scope of applications of the red surface-emitting laser. Thus, a device according to the present invention will entail a remarkably knock-on effect.

A single device is prepared in a manner as described above.

When a plurality of devices is to be integrally formed in array, for example, when 4×8=32 devices are arranged in array at a pitch of 50 μm, a photo-mask for arranging devices in a desired manner is employed from the beginning.

Then, a plurality of devices arranged in array can be formed simultaneously by using epiwafers same as the above-described one and following the same device forming process.

In other words, a red surface-emitting laser array can be obtained with ease by using a mask having a necessary pattern.

While an n-type GaAs substrate is used and p-type layers are made to be found as upper layers in the above description, alternatively a p-type GaAs substrate may be used and n-type layers may be made to be found as upper layers.

### Example 2

Now, Example 2 of the present invention will be described below.

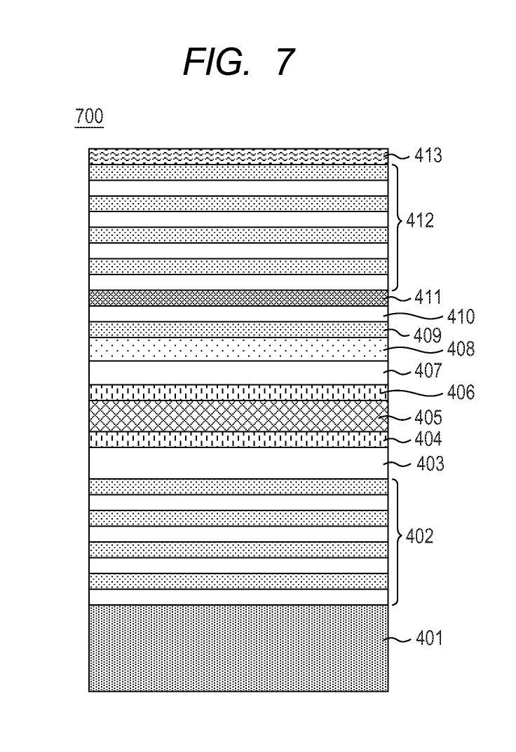

FIG. 7 is a schematic cross sectional view of red surface-emitting laser 700 according to the present invention, showing the layer arrangement thereof.

The VCSEL structure of this example is formed by using the layers listed below.

It comprises an n-type GaAs substrate 401, a DBR 402 formed by n-type AlAs/Al_{0.5}Ga_{0.5}As, a spacer layer 403 formed by n-type Al_{0.35}Ga_{0.15}In_{0.5}P, a barrier layer 404 formed by undoped Al_{0.25}Ga_{0.25}In_{0.5}P, a quantum well active layer 405 formed by Ga_{0.56}In_{0.44}P/Al_{0.25}Ga_{0.25}In_{0.5}P, a barrier layer 406 formed by undoped Al_{0.25}Ga_{0.25}In_{0.5}P, a spacer layer 407 formed by p-type Al_{0.5}In_{0.5}P, a third p-type intermediate layer 408 formed by p-type Al_{0.4}Ga_{0.1}In_{0.5}P, a second p-type intermediate layer 409 formed by p-type Al_{0.95}Ga_{0.05}As, a first p-type intermediate layer 410 formed by p-type Al_{0.5}Ga_{0.5}As, a selective oxidation layer 411 formed by p-type Al_{0.98}Ga_{0.05}As, a DBR 412 formed by p-type Al_{0.95}Ga_{0.05}As/Al_{0.5}Ga_{0.5}As and a p-type GaAs contact layer 413.

A red surface-emitting laser that oscillates with a wavelength of 680 nm is formed in this instance.

The n-type DBR 402 is made to be a reflector-forming layer in order to reduce the thermal resistance of the device and AlAs that is a low thermal resistance material is employed here instead of Al_{0.9}Ga_{0.1}As employed in Example 1.

The p-type DBR 412 is made to be a multilayer film reflector of p-type Al_{0.95}Ga_{0.05}As/Al_{0.5}Ga_{0.5}As in order to increase the difference of refractive index and increase the reflectance. When Al_{0.95}Ga_{0.05}As is employed for the second p-type intermediate layer 409, Al_{0.4}Ga_{0.1}In_{0.5}P is employed for the third p-type intermediate layer 408 in order to make ΔEv between the third p-type intermediate layer 408 and the second p-type intermediate layer 409 smaller than 20 meV. Then, ΔEv is about 13 meV so that any rise of drive voltage can be suppressed.

Each of the first p-type intermediate layer 410 formed by p-type Al_{0.5}Ga_{0.5}As and the second p-type intermediate layer 409 formed by p-type Al_{0.95}Ga_{0.05}As is made to have a thickness of λ/4n (n: refractive index of medium).

With this arrangement, both the first p-type intermediate layer 410 and the second p-type intermediate layer 409 have a thickness suitable for forming a p-type DBR and can operate to raise the reflectance as part of p-type DBR.

More specifically, the first p-type intermediate layer 410 formed by p-type Al_{0.5}Ga_{0.5}As and the second p-type intermediate layer 409 formed by p-type Al_{0.95}Ga_{0.05}As are made to have respective thicknesses of 49.1 nm and 54.5 nm. Since the refractive indexes of the two layers are respectively 3.46 and 3.12, their optical thicknesses are 170 nm, which is equal to ¼ of 680 nm.

In this example, a one-wavelength cavity having a configuration that is normally employed for a VCSEL is adopted. The optical thickness of a one-wavelength cavity with an oscillation wavelength of 680 nm is 680 nm.

The resonator refers to a region surrounded by the n-type DBR 402 and the p-type DBR 412 and hence is formed by the n-type spacer layer, the active layer, the p-type spacer layer and the third p-type intermediate layer.

The active layer needs to be arranged at the loop of the standing wave in order to maximize the interaction of light and carriers. In this instance, the active layer is arranged at the position of ½ from the center position in the 680 nm as viewed from the n-type side.

An actual example will be described below, taking the above requirements into consideration.

The active layer is formed as in Example 1, and an optical thickness thereof is 146 nm.

Like Example 1, an optical thickness of 340 nm, which is ½ of 680 nm, produced by adding 73 nm that is a half of the optical length of the active layer region, the optical thickness of the barrier layer 404 formed by undoped Al_{0.25}Ga_{0.25}In_{0.5}P and that of the spacer layer 403 formed by n-type Al_{0.35}Ga_{0.15}In_{0.5}P will be satisfactory.

At the p side, an optical thickness of the remaining 340 nm produced by adding 73 nm that is a half of the optical thickness of the active layer 405, the optical thickness of the barrier layer 406 formed by undoped Al_{0.25}Ga_{0.25}In_{0.5}P, that of the spacer layer 407 formed by p-type Al_{0.5}In_{0.5}P and that of the third p-type intermediate layer 408 formed by p-type Al_{0.4}Ga_{0.1}In_{0.5}P will be satisfactory.

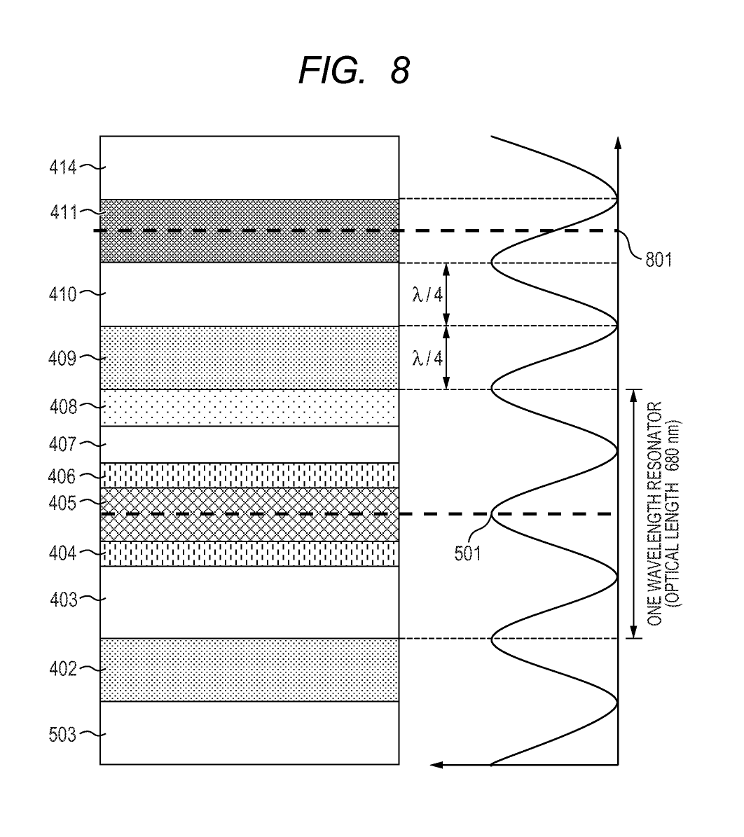

The barrier layer 406 formed by undoped Al_{0.25}Ga_{0.25}In_{0.5}P and the spacer layer 407 formed by p-type Al_{0.5}In_{0.5}P are made to have respective thicknesses same as those of their counterparts in Example 1. The remaining third p-type intermediate layer 408 formed by p-type Al_{0.4}Ga_{0.1}In_{0.5}P is made to have a thickness of 30.5 nm. Since its refractive index is 3.27, the optical thickness of the three layers becomes equal to 267 nm and the total optical thickness obtained by adding 73 nm, which is a half of the optical thickness of the active layer 405, becomes equal to 340 nm. Then, the center of the active layer is located at the loop 501 of the standing wave as shown in FIG. 8.

The optical thickness of the n layers including the undoped barrier layer, that of the active layer and that of the p layers including the undoped barrier layer are respectively 267 nm, 146 nm and 267 nm (with a total of 680 nm), which agrees with the optical thickness of the one-wavelength cavity.

A multilayer film reflector is formed at each side of the resonator. Both the multilayer film reflector at the n side and the multilayer film reflector at the p side are arranged in such a way that the loop of the standing wave agrees with the interfaces of the resonator and the multilayer film reflectors.

More specifically, a low refractive index material, which is the n-type AlAs layer in this instance, is made to adjoin the resonator and a high refractive index material, which is the Al_{0.5}Ga_{0.5}As layer 401 in this instance, is further arranged thereon. As for the p-type side, the selective oxidation layer formed by p-type Al_{0.98}Ga_{0.02}As is made to have a thickness of ¼ wavelength and adjoin the first p-type intermediate layer as a low refractive index material and a high refractive index material, which is the Al_{0.5}Ga_{0.5}As layer 401 in this instance, is further arranged thereon.

The component pairs are arranged repetitively for a necessary number of times both at the p-type side and at the n-type side (32 pairs for the p side and 60 pairs for the n side). Unlike Example 1, the p-type selective oxidation layer is arranged at a middle position 801 located between the loop and the node of the standing wave as shown in FIG. 8.

Thus, the first p-type intermediate layer and the second p-type intermediate layer are made to have a thickness of λ/4n (n: refractive index of medium) relative to the oscillation frequency λ so as to make part of the p-type DBR takes the role of the first p-type intermediate layer and the second p-type intermediate layer. Then, the high reflectance of the DBR can be maintained.

The device can be prepared as in Example 1 and a plurality of devices is to be integrally formed in array also as in Example 1. While a multiple quantum well structure is employed in Example 1 and Example 2, a periodic gain structure of arranging two or more multiple quantum well structures may alternatively be adopted. If such is the case, a two-wavelength cavity may be employed to make all the plurality of multiple quantum well structures to be located at the loops of the standing wave. By using a two-wavelength cavity, two loops are formed for the standing wave in the resonator and the multiple quantum well structures are arranged at the two loops.

### Example 3

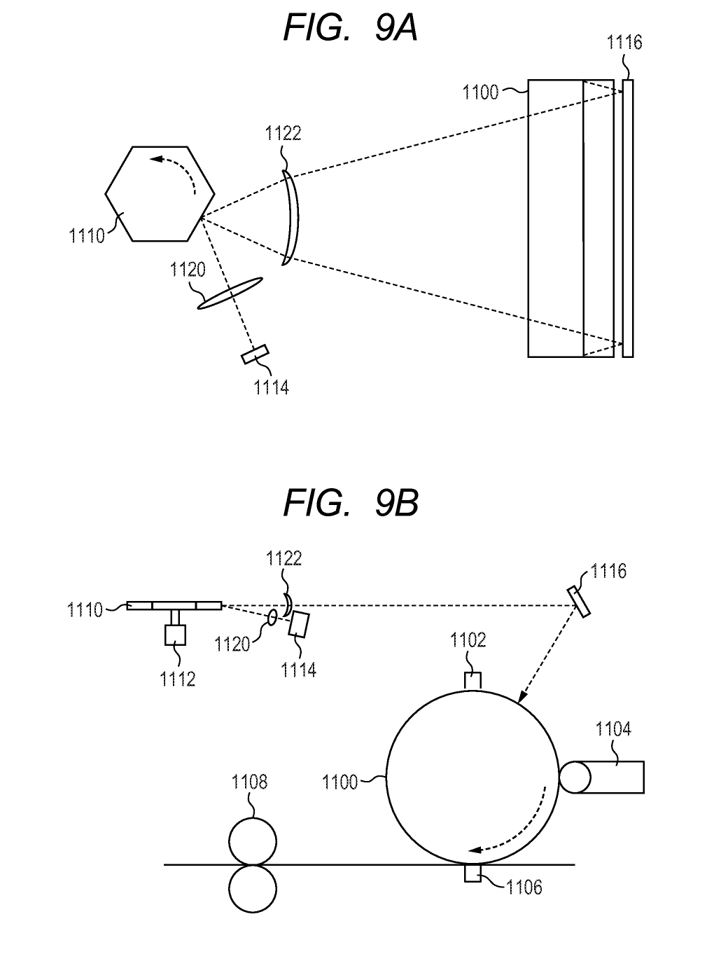

An image forming apparatus using a surface-emitting laser array light source formed by arranging a plurality of surface-emitting lasers having a configuration as illustrated above will be described below by referring to FIGS. 9A and 9B.

FIG. 9A is a schematic plan view of the image forming apparatus and FIG. 9B is a lateral view of the apparatus.

The laser beam output from a surface-emitting laser array light source 1114 that is designed to operate as recording light source is irradiated onto a rotating polygon mirror 1110 that is driven to rotate by a motor 1112 through a collimator lens 1120.

The laser beam irradiated to the rotating polygon mirror 1110 is reflected as a deflected beam whose emission angel continuously changes as the rotating polygon mirror 1110 rotates. The reflected laser beam is corrected for distortions and so on by an f-θ lens 1122 and irradiated to a photosensitive member 1100 by way of a reflector 1116.

The photosensitive member 1100 is electrically charged in advance by a charging apparatus 1102 and is exposed to the laser beam as the laser beam is scanned to form an electrostatic latent image. The electrostatic latent image formed on the photosensitive member 1100 is developed by a developing apparatus 1104 and the visible image produced as a result of the development is transferred onto a transfer sheet by a transfer charging apparatus 1106. The transfer sheet to which the visible image is transferred is conveyed to a fixing apparatus 1108 for fixation and then delivered to the outside of the apparatus after the fixation.

In this patent application, the meaning of “on” described in the claim and the specification may include “on” and “above”.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2010-121228, filed May 27, 2010, which is hereby incorporated by reference herein in its entirety.

What is claimed is:

1. A surface-emitting laser comprising:
an n-type semiconductor Bragg reflector arranged on a substrate:
an active layer including AlGaInP formed on the n-type semiconductor Bragg reflector;
a p-type spacer layer including AlInP formed on the active layer;
a selective oxidation layer including Al_{z}Ga_{1-z}As formed on the p-type spacer layer;
an p-type semiconductor Bragg reflector including AlGaAs formed on the selective oxidation layer;
a first intermediate layer including AlₓGa₁₋ₓAs arranged between the selective oxidation layer and the p-type spacer layer so as to adjoin the selective oxidation layer;
a second intermediate layer including Al_{y}Ga_{1-y}As arranged between the selective oxidation layer and the p-type spacer layer so as to adjoin the first intermediate layer; and
a third intermediate layer including AlGaInP arranged between the selective oxidation layer and the p-type spacer layer so as to adjoin the second intermediate layer,
wherein the z, y, x of the above material satisfy the relationship of z>y>x.

2. The surface-emitting laser according to claim 1, wherein the thickness of the second intermediate layer and that of the first intermediate layer are equal to an optical thickness of ¼ of a wavelength relative to the wavelength of oscillated light.

3. An image forming apparatus comprising:
a surface-emitting laser array formed by arranging a plurality of surface emitting laser according to claim 1;
a photosensitive member forming an electrostatic latent image by exposing a light emitted from the surface-emitting laser array;
a charging apparatus charging the photosensitive member electrically; and
a developing apparatus developing the electrostatic latent image.

4. A surface-emitting laser comprising an n-type semiconductor Bragg reflector, a p-type semiconductor Bragg reflector, and an active layer arranged between the reflectors, the reflectors and the active layer being laminated on a substrate, the p-type semiconductor Bragg reflector being arranged on the active layer through a p-type spacer layer and a selective oxidation layer, a current confinement structure being formed by oxidizing the selective oxidation layer, comprising:
a first intermediate layer arranged so as to adjoin the selective oxidation layer and included a material free from progress of oxidation when oxidizing the selective oxidation layer;
a second intermediate layer arranged so as to adjoin the first intermediate layer to adjust a difference between band gap values of the p-type spacer layer and the first intermediate layer; and
a third intermediate layer arranged so as to adjoin the second intermediate layer to adjust a difference between band gap values of the p-type spacer layer and the first intermediate layer,
wherein the first intermediate layer, the second intermediate layer, and the third intermediate layer are arranged between the selective oxidation layer and the p-type spacer layer.
